(19) United States
(12) Patent Application Publication
(10) Pub. No.: US 2025/0361614 A1
(43) Pub. Date: Nov. 27, 2025

(54) INCREASED LIFE SUBSTRATE SUPPORT ASSEMBLY

(71) Applicant: Applied Materials, Inc., Santa Clara, CA (US)

(72) Inventors: Ankit Atul GORATELA, Santa Clara, CA (US); Jian LI, Fremont, CA (US); Amit Kumar BANSAL, Milpitas, CA (US); Shailendra SRIVASTAVA, Fremont, CA (US); Emerson BRAITHWAITE, Santa Clara, CA (US); Ravi SIMHA, Bangalore (IN)

(21) Appl. No.: 18/669,718

(22) Filed: May 21, 2024

(51) Int. Cl. C23C 16/458; C23C 16/46

(52) U.S. Cl. CPC C23C 16/4581; C23C 16/46

(57) ABSTRACT

Embodiments herein are generally directed to a substrate support assembly for use in a plasma processing chamber. The substrate support assembly includes a support body, a support protrusion having a substrate support surface and extending from a top surface of the support body, an edge recess disposed along an outer edge of the support body, and an edge ring having an edge support surface and disposed on and removably coupled to the top surface of the support body, the edge ring being partially disposed in the edge recess. In another embodiment, a support ring is disposed on the top surface between the edge ring and the support protrusion. In yet another embodiment, an inner heating element and an outer heating element is embedded in the support body.

### BACKGROUND

### Field

Embodiments of the present disclosure generally relate to apparatus and methods for fabricating semiconductor devices. More specifically, apparatus disclosed herein relate to an electrostatic chuck assembly for use in a plasma processing chamber.

### Description of the Related Art

In semiconductor processing, particularly plasma enhanced chemical vapor deposition (PECVD) cleaning processes, fluorine radicals may be used during a cleaning process to remove contaminants from within a PECVD chamber. However, some components, such as a substrate support, may include metals, such as aluminum, that are susceptible to oxidation. When a substrate support or other chamber components include metals, like aluminum, the fluorine radicals of the cleaning plasma used in the cleaning process attack and oxidize the aluminum of the exposed surfaces.

Ceramic coatings are used to protect the aluminum from fluorine radical attack and plasma ion bombardment. However, exposure to the plasma can cause cracking in ceramic coatings used in PECVD processes. Additionally, the fluorine radicals are highly reactive and can cause damage to many materials, including ceramics. When the ceramic coatings are exposed to fluorine, the aggressive nature of the fluorine can lead to the degradation of the ceramic coating over time, which can also lead to cracking.

Accordingly, there is a need for improved systems and methods to protect substrate supports from damaging oxidation.

### SUMMARY

Embodiments herein are generally directed to apparatus and methods for fabricating semiconductor devices and, more particularly, to an electrostatic chuck or substrate support assembly for use in a plasma processing chamber.

In an embodiment, a substrate support assembly is provided. The substrate support assembly includes a support body, a support protrusion having a substrate support surface and extending from a top surface of the support body, an edge recess disposed along an outer edge of the support body, and an edge ring having an edge support surface and disposed on and removably coupled to the top surface of the support body, the edge ring being partially disposed in the edge recess.

In another embodiment, a substrate support assembly is provided. The substrate support assembly includes a support body a support protrusion having a substrate support surface and extending from a top surface of the support body, an edge ring disposed on and removably coupled to an outer edge of the support body, and a support ring disposed on the top surface between the edge ring and the support protrusion.

In yet another embodiment, a substrate support assembly is provided. The substrate support assembly includes a support body, a support protrusion having a substrate support surface and extending from a top surface of the support body, an edge ring disposed on and removably coupled to an outer edge of the support body, a support ring disposed on the top surface between the edge ring and the support protrusion, an inner heating element embedded in the support body, and an outer heating element embedded in the support body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 illustrates a schematic, cross-sectional side view of a plasma processing chamber, according to certain embodiments

FIG. 2 illustrates a schematic, cross-sectional view of a portion of a substrate support assembly, according to certain embodiments.

FIG. 3 illustrates a schematic, cross-sectional view of a portion of the substrate support assembly, according to certain embodiments.

FIG. 4 illustrates a schematic, cross-sectional view of a portion of the substrate support assembly, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to apparatus and methods for fabricating semiconductor devices and, more particularly, to an electrostatic chuck assembly for use in a plasma processing chamber.

In semiconductor processing, particularly plasma enhanced chemical vapor deposition (PECVD) processes, fluorine radicals are used during a cleaning process to remove contaminants from within a PECVD chamber. However, some chamber components, such as a substrate support, typically include metals, such as aluminum, that are susceptible to oxidation. When a substrate support or other chamber components include metals, like aluminum, the fluorine radicals of the cleaning plasma used in the cleaning process attack and oxidize the aluminum of the exposed surfaces.

Fluorine-containing gases such as sulfur hexafluoride (SF₆) and nitrogen trifluoride (NF₃) are widely used in plasma etching due to the efficient reactions of fluorine radicals. However, aluminum is easily oxidized, and fluorine, an aggressive oxidizer, reacts with the aluminum to form aluminum fluoride (AlF₃). This reaction is facilitated by the particle bombardment activated reaction, producing etch products in the form of AlF₃ or aluminum oxyfluoride (AlOxFy). These etch products are nonvolatile but have a higher sputtering yield than aluminum oxide.

This process results in the accumulation of a layer of aluminum fluoride contaminant on these surfaces. The contamination causes the surface to become rougher and the wall of the chamber and parts to become thinner as the conversion of aluminum to aluminum fluoride eats away at the underlying materials. In addition, the reaction adds another contaminant to the etching process.

The substrate support is particularly vulnerable to attack by fluorine during cleaning processes, and if the concentration of fluorine is continuously increased, the substrate support can be broken. Therefore, managing the interaction of fluorine radicals with aluminum surfaces is necessary in PECVD processes to ensure the longevity of the equipment and the quality of the semiconductor devices produced.

To address the issue of fluorine oxidation of aluminum components, ceramic coatings may be used to protect the aluminum from fluorine radical attack. The ceramic coating acts as a barrier between the aluminum surfaces and the fluorine radicals, thereby reducing the direct contact between them. This coating is typically applied to the internal components of the PECVD chamber, including the substrate support.

However, exposure to plasma ions, can cause cracking in ceramic coatings used in PECVD processes. Bombardment by ions or radicals when the plasma is formed and biased may strike the ceramic coating and damage its surface.

The cracking of ceramic coatings may be also related to the stress in the thin films and coatings. The stress in these coatings can be due to various factors, including the deposition process, the properties of the materials used, and the operating conditions. Moreover, the bombardment of the material surface by low-energy ions can lead to breakage of chemical bonds, surface diffusion, and heating, which contribute to film densification and to enhanced film-substrate adhesion. However, this can also favor the molecular dissociative chemisorption, which can lead to cracking.

The present disclosure provides for an apparatus and system to prevent oxidation of a substrate support during cleaning processes. The present disclosure provides a substrate support assembly including a support body having a support protrusion. The support protrusion has a substrate support surface and extends from a top surface of the support body. The substrate support assembly also includes an edge recess disposed along an outer edge of the support body that an edge ring may be partially disposed in, e.g., by an edge ring protrusion, and removably coupled to the top surface of the support body. The top surface acts as an undercut of the support protrusion to allow for the edge ring to properly support a substrate. The edge ring also protects the support body from oxidation by fluorine ions during a cleaning process in the PECVD chamber, extending the useful lifetime of the substrate support assembly and reducing maintenance cost.

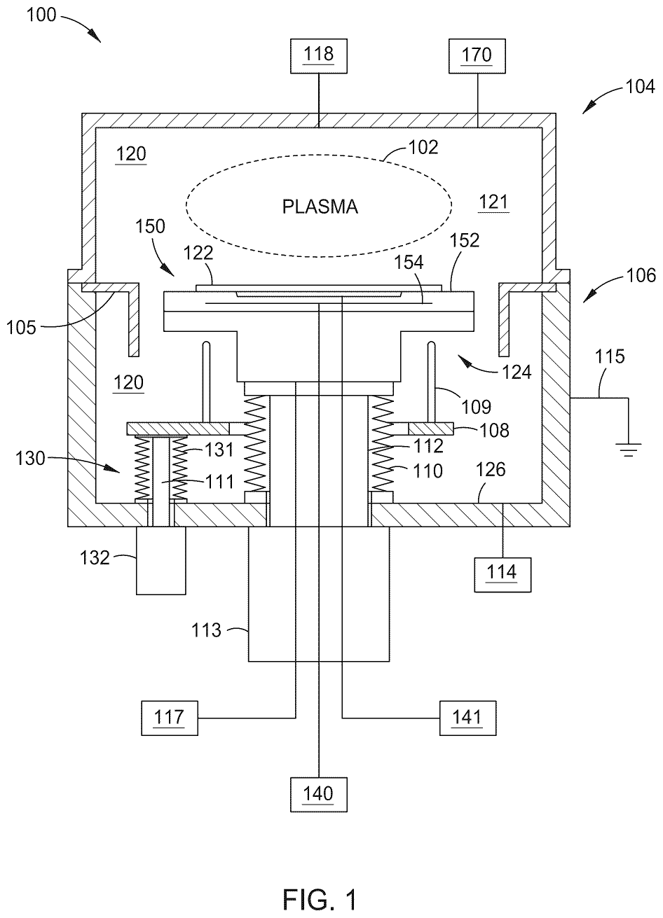

FIG. 1 shows a schematic side view of a plasma processing chamber 100 having a substrate support 124, according to certain embodiments. In some examples, the plasma processing chamber 100 is a processing chamber configured to perform etch processes. However, other types of processing chambers configured for different processes can also use or be modified for use with examples of the substrate support 124 described herein.

The plasma processing chamber 100 is a vacuum chamber that is suitably adapted to maintain sub-atmospheric pressures within a chamber interior volume 120 during substrate processing. The plasma processing chamber 100 includes a chamber body 106 covered by a lid 104 which encloses a processing volume 121 located in the upper portion of the chamber interior volume 120 and generally above the substrate support 124. The plasma processing chamber 100 may also include one or more liners 105 circumscribing various chamber components to prevent unwanted reaction between such components and the gases of the processing environment within the plasma processing chamber 100. The chamber body 106 and lid 104 may be made of metal, such as aluminum. The chamber body 106 may be grounded via a coupling, such as a ground strap, to ground 115.

The substrate support 124 is disposed within the chamber interior volume 120 to support and retain a substrate 122 thereon, such as a semiconductor substrate. The substrate support 124 may generally comprise an electrostatic chuck assembly 150 and a hollow support shaft 112 for supporting the electrostatic chuck assembly 150. The electrostatic chuck assembly 150 comprises an electrostatic chuck 152 having one or more chucking electrodes 154 disposed therein. The electrostatic chuck 152 electrostatically chucks the substrate 122 to the substrate support 124.

The hollow support shaft 112 provides a conduit to provide, for example, backside gases through backside gas lines, process gases through process gas lines, fluids through fluid lines, coolants through coolant lines, power cabling, or the like, to the substrate support 124. In some examples, the hollow support shaft 112 is attached to a bottom surface of the chamber body 106 and the substrate support 124 is fixed in the plasma processing chamber 100. In other examples, the hollow support shaft 112 is coupled to a lift mechanism 113, such as an actuator or motor, which provides vertical movement of the electrostatic chuck assembly 150 between an upper, processing position (as shown in FIG. 1) and a lower, transfer position (not shown). A bellows assembly 110 is disposed about the hollow support shaft 112 and is coupled between the electrostatic chuck assembly 150 and a bottom surface 126 of plasma processing chamber 100 to provide a flexible seal that allows vertical motion of the electrostatic chuck assembly 150 while preventing loss of vacuum from within the plasma processing chamber 100.

The hollow support shaft 112 provides a conduit for coupling wiring or other electrical conductors between a negative pulsed DC power source 140 and/or a bias power supply 117 to the electrostatic chuck assembly 150, as well as, where desired, a conduit for a backside gas supply 141 to supply gas through optional passages in the electrostatic chuck assembly 150 and openings in the substrate support portion of the substrate and thereby locate a heat transfer gas between a substrate and the electrostatic chuck assembly 150. In some examples, the bias power supply 117 includes one or more RF bias power sources. Where the backside gas supply 141 is used, it is disposed outside of the chamber body 106 and supplies heat transfer gas to the electrostatic chuck assembly 150 through a conduit in the hollow support shaft. In some examples, the substrate support 124 may alternatively include AC, DC, or RF bias power.

The substrate support 124 may, or may not, include a substrate lift assembly 130. The substrate lift assembly 130 may include lift pins 109 mounted on a platform 108 connected to a shaft 111 which is coupled to a second lift mechanism 132 for raising and lowering the platform 108 and lift pins 109 so that the substrate 122 may be placed on or removed from the electrostatic chuck assembly 150. The electrostatic chuck assembly 150 includes through holes to receive the lift pins 109. A bellows assembly 131 is coupled between the substrate lift assembly 130 and the bottom surface 126 to provide a flexible seal that maintains the chamber vacuum during vertical motion of the substrate lift assembly 130. Alternately, the substrate lift assembly 130 may be included entirely inside the plasma processing chamber 100, for example within the substrate support 124.

The plasma processing chamber 100 is coupled to and in fluid communication with a pumping system 114 that includes a throttle valve (not shown) and vacuum pump (not shown) which are used to exhaust the plasma processing chamber 100. The pressure inside the plasma processing chamber 100 may be regulated by adjusting the throttle valve and/or vacuum pump. The plasma processing chamber 100 is also coupled to and in fluid communication with a process gas supply 118 that may supply one or more process gases to the plasma processing chamber 100 for processing the substrate 122 disposed therein.

In operation, a plasma 102 is created in the chamber interior volume 120 to perform one or more processes. The plasma 102 may be created by coupling power from a plasma power source (e.g., RF plasma power supply 170) to a process gas via one or more electrodes (for example a coil not shown) near and exterior to the lid 104, or within the chamber interior volume 120, to ignite the process or other gas therein into a plasma 102. A bias power may also be provided from the bias power supply 117 to the one or more chucking electrodes 154 within the electrostatic chuck assembly 150 (in addition to the chucking power) to attract ions from the plasma 102 towards the substrate 122 to etch the exposed upper surface of the substrate 122. Alternatively, a separate substrate/body biasing electrode may be buried within the ceramic body and connected to a separate or common power supply. The RF plasma power supply 170 may provide RF energy at a frequency of about 40 MHz or greater to the plasma processing chamber 100 for maintaining the plasma 102 therein.

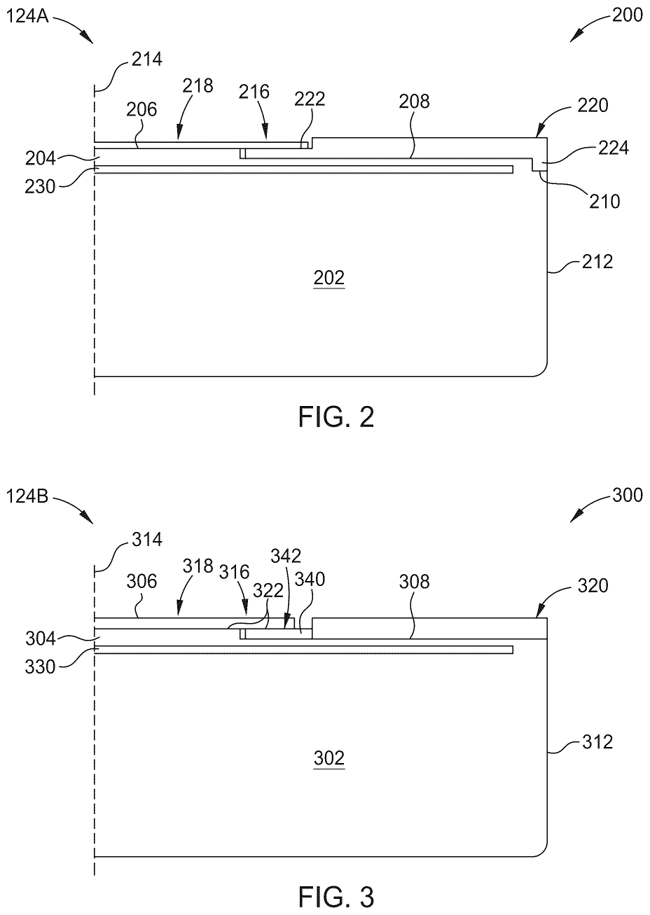

FIG. 2 illustrates a schematic, cross-sectional view of a portion 200 of a substrate support assembly 124A, according to certain embodiments.

As shown in FIG. 2, the portion 200 of substrate support assembly 124A includes a support body 202 having a support protrusion 204. The support protrusion 204 has a substrate support surface 206 and extends from a top surface 208 of the support body 202. The support body 202 includes an edge recess 210 disposed along an outer edge 212 of the support body 202. The substrate support assembly 124A further includes an edge ring 220 disposed on and removably coupled to the top surface 208 of the support body 202 along the outer edge 212 of the support body 202. The edge ring 220 has an edge support surface 222 opposite the outer edge 212 and configured to support a substrate during processing. The edge support surface 222 is configured to support an outer portion 216 of a substrate. For example, for a 300 mm substrate, the outer portion 216 of the substrate may include a portion of the substrate that is 5 mm or less from an outer edge of the substrate, such as about 3 mm from the outer edge of the substrate. The substrate support surface 206 of the support protrusion 204 is configured to support an inner portion 218 of a substrate. For example, for a 300 mm substrate, the inner portion 218 of the substrate may include a portion of the substrate that has a diameter of 297 mm or less, such as about 295 mm or less, from the support body center axis 214. The edge support surface 222 and the substrate support surface 206 are coplanar such that a substrate is supported evenly when disposed on the substrate support surface 206 and the edge support surface 222. The edge ring 220 further includes an edge ring protrusion 224 that is disposed in the edge recess 210. The edge ring protrusion 224 allows for consistent alignment of the edge ring 220 on the top surface 208 of the support body 202 and prevents the edge ring 220 from displacing while a substrate disposed on the substrate support assembly 124A is being processed. The substrate support assembly 124A further includes a heating element 230 embedded in the support body 202 and configured to heat a substrate during processing. The heating element 230 is embedded in the support body 202 beneath the support protrusion 204 and the edge ring 220. The heating element 230 extends radially outward from a support body center axis 214 of the support body 202 and ends before the edge recess 210.

The top surface 208 may act as an undercut of the support protrusion 204 to allow the top surface 208 to be recessed compared to the substrate support surface 206 of the support protrusion 204. This allows for the top surface 208 of the support body 202 to not contact a substrate disposed on the substrate support assembly 124A and allows for the edge support surface 222 of edge ring 220 to be coplanar to the substrate support surface 206 of the support protrusion 204. The edge ring 220 then protects the undercut portion of the support body 202, e.g., the top surface 208, from corrosion by cleaning gases, such as fluorine, during high temperature cleaning of the processing chamber without the need for a ceramic coating disposed over the entirety of the support body 202. As such, the edge ring 220 may include materials resistant to the cleaning gases, such as silicon (Si), silicon carbide (SiC), aluminum nitride (AlN), and quartz. The edge ring 220 becomes a consumable part, reducing maintenance cost and extending the usable lifetime of the support body 202.

FIG. 3 illustrates a schematic, cross-sectional view of a portion 300 of a substrate support assembly 124B, according to certain embodiments.

As shown in FIG. 3, the portion of the substrate support assembly 124B includes a support body 302 having a support protrusion 304. The support protrusion 304 has a substrate support surface 306 and extends from a top surface 308 of the support body 302. The substrate support assembly 124B includes an edge ring 320 disposed on and removably coupled to an outer edge 312 of the support body 302. The substrate support assembly 124B also includes a support ring 340 disposed on the top surface 308 between the edge ring 320 and the support protrusion 304. The support ring 340 further includes a support ring surface 342 configured to support an outer portion 316 of a substrate. The substrate support surface 306 of the support protrusion 304 is configured to support an inner portion 318 of a substrate. The support ring surface 342 is configured to support an outer portion 316 of a substrate. For example, for a 300 mm substrate, the outer portion 316 of the substrate may include a portion of the substrate that is 5 mm or less from an outer edge of the substrate, such as about 3 mm from the outer edge of the substrate. The substrate support surface 306 of the support protrusion 204 is configured to support an inner portion 318 of a substrate. For example, for a 300 mm substrate, the inner portion 318 of the substrate may include a portion of the substrate that has a diameter of 297 mm or less, such as about 295 mm or less, from the support body center axis 314. The support ring surface 342 and the substrate support surface 306 of the support protrusion 304 may be coplanar such that a substrate is supported evenly when disposed on the substrate support surface 306 and the support ring surface 342.

The substrate support assembly 124B further includes a heating element 330 embedded in the support body 302. The heating element 330 extends radially outward from a support body center axis 314 of the support body 302 and ends before the outer edge 312 of the support body 302. The heating element 330 extends under the support protrusion 304, the support ring 340, and the edge ring 320.

Similar to the substrate support assembly 124A, the top surface 308 may act as an undercut of the support protrusion 304 to allow the top surface 308 to be recessed compared to the substrate support surface 306 of the support protrusion 304. This allows for the top surface 308 of the support body 302 to not contact a substrate disposed on the substrate support assembly 124B and allows for the support ring surface 342 of the support ring 340 to be coplanar to the substrate support surface 306 of the support protrusion 304. The edge ring 320, in conjunction with the support ring 340, protects the outer portion of the support body 302 from corrosion by cleaning gases, such as fluorine, during high temperature cleaning of the processing chamber. The support ring 340 is disposed generally under the outer portion 316 of a substrate disposed on a substrate processing surface 322, defined by the substrate support surface 306 and support ring surface 342, and prevents process gases, including cleaning gases, from accessing the top surface 308 disposed beneath the outer portion 316. The edge ring 320 may include materials resistant to the cleaning gases, such as silicon (Si), silicon carbide (SiC), aluminum nitride (AlN), and quartz. The edge ring 320 becomes a consumable part, reducing maintenance cost and extending the usable lifetime of the support body 302. Using the support ring 340 along with the edge ring 320 improves manufacturability of the edge ring 320 while still allowing the edge ring 320 to be an effective protective barrier for the support body 302. The support ring 340 may include materials resistant to the cleaning gases, such as silicon (Si), silicon carbide (SiC), aluminum nitride (AlN), and quartz.

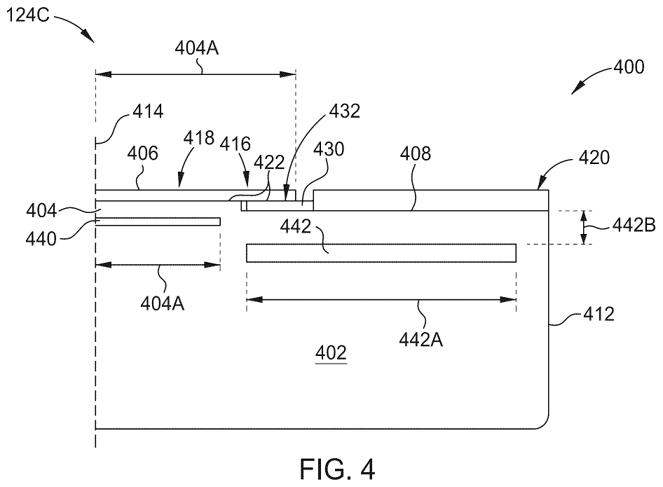

FIG. 4 illustrates a schematic, cross-sectional view of a portion 400 of the substrate support assembly 124C, according to certain embodiments.

As shown in FIG. 4, the portion 400 of the substrate support assembly 124C includes a support body 402 having a support protrusion 404. The support protrusion 404 has a substrate support surface 406 and extends from a top surface 408 of the support body 402. The substrate support assembly 124C includes an edge ring 420 disposed on and removably coupled to an outer edge 412 of the support body 402. The substrate support assembly 124C also includes a support ring 430 disposed on the top surface 408 between the edge ring 420 and the support protrusion 404. The support ring 430 further includes a support ring surface 432 configured to support an outer portion 416 of a substrate. The substrate support surface 406 of the support protrusion 404 is configured to support an inner portion 418 of a substrate. The support ring surface 432 is configured to support an outer portion 416 of a substrate. For example, for a 300 mm substrate, the outer portion 416 of the substrate may include a portion of the substrate that is 5 mm or less from an outer edge of the substrate, such as about 4 mm from the outer edge of the substrate. The substrate support surface 406 of the support protrusion 204 is configured to support an inner portion 418 of a substrate. For example, for a 300 mm substrate, the inner portion 418 of the substrate may include a portion of the substrate that has a diameter of 297 mm or less, such as about 295 mm or less, from a support body center axis 414. The support ring surface 432 and the substrate support surface 406 of the support protrusion 404 may be coplanar such that a substrate is supported evenly when disposed on the substrate support surface 406 and the support ring surface 432.

An inner heating element 440 is embedded in the support body 402. Further, an outer heating element 442 is also embedded in the support body 402. The inner heating element 440 extends radially from the support body center axis 414 and has an inner heating element radius 440A that is less than a protrusion radius 404A of the support protrusion 404. The outer heating element 442 has an outer heating element radius 442A that extends beneath the edge ring 420 and does not overlap the inner heating element 440. The outer heating element radius 442A extends under the support ring 430. The outer heating element 442 and the inner heating element 440 are concentric about the support body center axis 414 but not coplanar.

The inner heating element 440 is a first distance 440B from the top surface 408 of the support body 402. Similarly, the outer heating element 442 is a second distance 442B from the top surface 408 of the support body 402. As shown in FIG. 4, the first distance 440B is substantially equal to the second distance 442B. Alternatively, the first distance 440B may differ from the second distance 442B as desired. Having the dual heater configuration, e.g., the inner heating element 440 and the outer heating element 442 at independent distances, allows for the support protrusion 404 to be further away from the top surface 408, which raises the substrate support surface 406 further away from the support body 402. The independent distances, e.g., the first distance 440B and the second distance 442B, also allows for more bulk material of the support body 402 to be between the outer heating element 442 and the edge ring 420 and support ring 430 to provide the desired heating profile to be applied to the substrate support surface 406 and the top surface 408.

The substrate support surface 406 of the support protrusion 404 is configured to support an inner portion 418 of a substrate and wherein the support ring 430 further includes a support ring surface 432 configured to support an outer portion 416 of a substrate, the support ring surface 432 and the substrate support surface 406 of the support protrusion 404 are coplanar.

Similar to the substrate support assembly 124A, the top surface 408 may act as an undercut of the support protrusion 404 to allow the top surface 408 to be recessed compared to the substrate support surface 406 of the support protrusion 404. This allows for the top surface 408 of the support body 402 to not contact a substrate disposed on the substrate support assembly 124B and allows for the support ring surface 432 of the support ring 430 to be coplanar to the substrate support surface 406 of the support protrusion 404. The combination of the outer heating element 442 and the inner heating element 440 delivers the desired heating energy to be delivered to the support body. However, the outer heating element 442 and the inner heating element 440 do not have to be co-planar, e.g., the outer heating element 442 may be lower along a z-axis of the support body 402. For example, when the outer heating element 442 is lower than the inner heating element 440, the outer heating element 442 may be a desired distance from the top surface 408, which allows for additional tuning of the heating profile of the top surface 408 and the substrate support surface 406 as there is more bulk material, e.g., aluminum, between the outer heating element 442 and the top surface 408.

The edge ring 420 in conjunction with the support ring 430 protect the outer portion of the support body 402 from corrosion by cleaning gases, such as fluorine, during high temperature cleaning of the processing chamber. The support ring 430 is disposed generally under the outer portion 416 of a substrate disposed on a substrate processing surface 422, defined by the substrate support surface 406 and support ring surface 432, and prevents process gases, including cleaning gases, from accessing the top surface 408 disposed beneath the outer portion 416. The edge ring 420 may include materials resistant to the cleaning gases, such as silicon (Si), silicon carbide (SiC), aluminum nitride (AlN), and quartz. The edge ring 420 becomes a consumable part, reducing maintenance cost and extending the usable lifetime of the support body 402. Using the support ring 430 along with the edge ring 420 improves manufacturability of the edge ring 420 while still allowing the edge ring 420 to be an effective protective barrier for the support body 402. The support ring 430 may include materials resistant to the cleaning gases, such as silicon (Si), silicon carbide (SiC), aluminum nitride (AlN), and quartz.

The present disclosure provides for a substrate support assembly that includes a support protrusion extending from a top surface of a support body. The top surface acts as an undercut of the support protrusion to allow for an edge ring to properly support a substrate along with the support protrusion. The edge ring also protects the support body from oxidation by fluorine ions during a cleaning process, e.g., in a PECVD chamber, extending the useful lifetime of the substrate support assembly and reducing maintenance cost.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate support assembly, comprising:
a support body;
a support protrusion having a substrate support surface and extending from a top surface of the support body;
an edge recess disposed along an outer edge of the support body; and
an edge ring having an edge support surface and disposed on and removably coupled to the top surface of the support body, the edge ring being partially disposed in the edge recess.

2. The substrate support assembly of claim 1, wherein the edge support surface and the substrate support surface are coplanar.

3. The substrate support assembly of claim 1, wherein the edge ring further comprises an edge ring protrusion, and wherein the edge ring protrusion is disposed in the edge recess.

4. The substrate support assembly of claim 1, further comprising a heating element embedded in the support body.

5. The substrate support assembly of claim 4, wherein the heating element extends radially outward from a support body center of the support body and ends before the edge recess.

6. The substrate support assembly of claim 1, wherein the edge support surface is configured to support an outer portion of a substrate.

7. The substrate support assembly of claim 1, wherein the substrate support surface of the support protrusion is configured to support an inner portion of a substrate.

8. A substrate support assembly, comprising:
a support body:
a support protrusion having a substrate support surface and extending from a top surface of the support body;
an edge ring disposed on and removably coupled to an outer edge of the support body; and
a support ring disposed on the top surface between the edge ring and the support protrusion.

9. The substrate support assembly of claim 8, wherein the substrate support surface of the support protrusion is configured to support an inner portion of a substrate.

10. The substrate support assembly of claim 8, wherein the support ring further comprises a support ring surface configured to support an outer portion of a substrate.

11. The substrate support assembly of claim 10, wherein the support ring surface and the substrate support surface of the support protrusion are coplanar.

12. The substrate support assembly of claim 8, further comprising a heating element embedded in the support body.

13. The substrate support assembly of claim 12, wherein the heating element extends radially outward from a support body center of the support body and ends before the outer edge of the support body.

14. The substrate support assembly of claim 12, wherein the heating element extends under the support protrusion, the support ring, and the edge ring.

15. A substrate support assembly, comprising:
a support body;
a support protrusion having a substrate support surface and extending from a top surface of the support body;
an edge ring disposed on and removably coupled to an outer edge of the support body;
a support ring disposed on the top surface between the edge ring and the support protrusion;
an inner heating element embedded in the support body; and
an outer heating element embedded in the support body.

16. The substrate support assembly of claim 15, wherein the inner heating element extends radially from a support body center and has an inner heating element radius that is less than a protrusion radius of the support protrusion.

17. The substrate support assembly of claim 16, wherein the outer heating element has an outer heating element radius that extends beneath the edge ring and does not overlap the inner heating element.

18. The substrate support assembly of claim 17, wherein the outer heating element radius extends under the support ring.

19. The substrate support assembly of claim 15, wherein the outer heating element and the inner heating element are concentric but not coplanar.

20. The substrate support assembly of claim 15, wherein the substrate support surface of the support protrusion is configured to support an inner portion of a substrate and wherein the support ring further comprises a support ring surface configured to support an outer portion of a substrate, the support ring surface and the substrate support surface of the support protrusion are coplanar.
